(19) United States
(12) Patent Application Publication
(10) Pub. No.: US 2025/0315086 A1
(43) Pub. Date: Oct. 9, 2025

(54) DISPLAY APPARATUS

(71) Applicant: Samsung Display Co., LTD., Yongin-si (KR)

(72) Inventors: Taewoong KIM, Yongin-si (KR); Beomjin KIM, Yongin-si (KR); Sangjun LEE, Yongin-si (KR)

(21) Appl. No.: 19/037,625

(22) Filed: Jan. 27, 2025

(30) Foreign Application Priority Data
Apr. 3, 2024 (KR) 10-2024-0045569

(51) Int. Cl. G06F 1/16

(52) U.S. Cl. CPC G06F 1/1652; G06F 1/1656

(57) ABSTRACT

A display apparatus includes a shaft extending in a first direction and including a first half ring portion having a curvature from a first end portion to a second end portion opposite to the first end portion on a plane perpendicular to the first direction, and a second half ring portion having a curvature from a third end portion to a fourth end portion opposite to the third end portion on the plane. The third end portion and the fourth end portion of the second half ring portion are respectively connected to the first end portion and the second end portion of the first half ring portion. The display apparatus includes a groove arranged adjacent to the first end portion of the first half ring portion. The display apparatus includes a base layer including a protrusion fitted into the groove.

This application claims priority to Korean Patent Application No. 10-2024-0045569, filed on Apr. 3, 2024, and all the benefits accruing therefrom under 35 U.S.C. § 119, the content of which in its entirety is herein incorporated by reference.

### BACKGROUND

### 1. Field

One or more embodiments relate to a display apparatus, and more particularly, to a rollable display apparatus for which a defect occurrence rate is reduced.

### 2. Description of the Related Art

Recently, electronic devices have been widely used. Electronic devices are used in various ways, such as, for example, mobile electronic devices and fixed electronic devices. Such electronic devices may include display apparatuses capable of providing visual information, such as, for example, images or videos, to users in support of various functions.

Generally, a display apparatus may include a display module capable of displaying an image. Such display apparatuses may be used in various fields, and special characteristics may be implemented for display apparatuses according to usage environment. For example, curved display apparatuses that are bent at a preset curvature, foldable display apparatuses that are foldable around a certain folding shaft, or rollable display apparatuses that are rollable around a virtual axis may have flexible characteristics. In the case of such conventional display apparatuses, defects may occur in the display apparatuses due to stress occurring when utilizing such functions.

The background art is technical information possessed by the inventors for the derivation of the disclosure or obtained during the derivation of the disclosure, and is not necessarily known technology disclosed to the general public prior to the filing of the disclosure.

### SUMMARY

One or more embodiments include a rollable display apparatus in which a defect occurrence rate is reduced.

However, the reduction of the defect occurrence rate is an example, and the technical problems to be solved by the disclosure are not limited thereto.

Additional aspects will be set forth in part in the description which follows and, in part, will be apparent from the description, or may be learned by practice of the presented embodiments of the disclosure.

According to one or more embodiments, a display apparatus includes a shaft extending in a first direction and including a first half ring portion having a curvature from a first end portion to a second end portion opposite to the first end portion on a plane perpendicular to the first direction, and a second half ring portion having a curvature from a third end portion to a fourth end portion opposite to the third end portion on the plane, wherein the third end portion and the fourth end portion of the second half ring portion are respectively connected to the first end portion and the second end portion of the first half ring portion, a groove arranged adjacent to the first end portion of the first half ring portion and concavely formed from an outer surface of the first half ring portion in a thickness direction of the first half ring portion, a base layer configured to overlap the first half ring portion and the second half ring portion from the first end portion in a wound state of the display apparatus, the base layer including a protrusion fitted into the groove, and a display module disposed on the base layer.

In an embodiment, a width of the groove may increase from the outer surface to an inner surface of the first half ring portion.

In an embodiment, the groove may be trapezoidal shaped, and the protrusion may be trapezoidal shaped corresponding to the shape of the groove.

In an embodiment, a thickness of the third end portion of the second half ring portion may be greater than a thickness of the first end portion of the first half ring portion, and the second half ring portion may have a stepped surface, where a thickness of the stepped surface SS may be greater than a thickness of the first end portion at the third end portion.

In an embodiment, the base layer may be fixed to the second half ring portion by an adhesive layer between the base layer and the stepped surface of the second half ring portion.

In an embodiment, a difference between a difference between a thickness of the third end portion of the second half ring portion and a thickness of the first end portion of the first half ring portion and a sum of a thickness of the base layer and a thickness of the display module may be 40 μm or less.

In an embodiment, the display module may include a display panel configured to display an image, and a cover window disposed such that the cover window covers the display panel.

In an embodiment, the display module may further include a protection film between the display panel and the base layer.

In an embodiment, an outer surface of the second end portion of the first half ring portion and an outer surface of the fourth end portion of the second half ring portion, which are connected to each other, may form a continuous surface.

In an embodiment, a thickness of the shaft continuously may vary over the first end portion of the first half ring portion to the second end portion of the first half ring portion, and the thickness of the shaft may continuously vary over the fourth end portion of the second half ring portion to the third end portion of the second half ring portion.

In an embodiment, a thickness of the first end portion of the first half ring portion may be less than a thickness of the second end portion of the first half ring portion.

In an embodiment, a thickness of the fourth end portion of the second half ring portion may be less than a thickness of the third end portion of the second half ring portion.

In an embodiment, a curvature radius associated with an outer surface of the first half ring portion and a curvature radius associated with an outer surface of the second half ring portion may each continuously vary.

In an embodiment, the curvature radius associated with the outer surface of the first half ring portion and the first end portion may be less than the curvature radius associated with the outer surface of the first half ring portion and the second end portion.

In an embodiment, the curvature radius associated with the outer surface of the second half ring portion and the fourth end portion may be less than the curvature radius associated with the outer surface of the second half ring portion and the third end portion.

In an embodiment, the base layer may include a basic layer and a plurality of supports arranged in parallel with each other within the basic layer and each extending in the first direction.

In an embodiment, the basic layer may include silicon or polyurethane acrylate.

In an embodiment, the base layer may include a dummy area in which the protrusion is arranged and a support area connected to the dummy area, and the dummy area may wrap around the shaft one or more times in the wound state of the display apparatus, where a quantity of times by which the dummy area wraps around the shaft may be based on a length of the dummy area.

In an embodiment, the plurality of supports may not be arranged in the dummy area and may be arranged in the support area.

According to one or more embodiments, a display apparatus includes a shaft including a central shaft, a first end portion, a stepped surface, and an outer surface, where, when viewed in a direction of the central shaft, the outer surface is spiral shaped and includes one rotation starting from the first end portion to the stepped surface with respect to the central shaft, a groove concavely formed from the outer surface of the shaft at the first end portion in a thickness direction, a base layer fitted into the groove and configured to overlap the outer surface of the shaft in a wound state of the display apparatus, and a display module disposed on the base layer.

Other aspects, features, and advantages of the disclosure will become better understood through the detailed description, the claims, and the accompanying drawings.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic exploded perspective view of a display apparatus according to an embodiment;

FIG. 2 is a schematic cross-sectional view of the display apparatus of FIG. 1 taken along line II-II′ of FIG. 1, according to an embodiment;

FIG. 3 is a schematic cross-sectional view of a display apparatus according to an embodiment and may be similar to FIG. 2;

FIG. 4 is a schematic cross-sectional view of a display portion according to an embodiment;

FIG. 5 is a schematic perspective view of a base layer according to an embodiment; and

FIG. 6 is a schematic cross-sectional view of a display panel according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described herein, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in detail in the written description. Effects and features of the disclosure, and methods of achieving them will be clarified with reference to embodiments described herein in detail with reference to the drawings. However, the disclosure is not limited to the following embodiments and may be embodied in various forms.

Hereinafter, embodiments will be described in detail with reference to the accompanying drawings. When describing embodiments with reference to the accompanying drawings, the same or corresponding elements are denoted by the same reference numerals, and redundant descriptions thereof are omitted.

In the following embodiments, the terms “first,” “second,” and the like are not used in a restrictive sense and are used to distinguish one element from another.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

It will be further understood that, when a layer, region, or element is referred to as being “on” another layer, region, or element, this may be directly on the other layer, region, or element, but also intervening layers, regions, or elements may be present therebetween.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

In some aspects, sizes of elements in the drawings may be exaggerated or reduced for convenience of explanation. For example, because sizes and thicknesses of elements in the drawings are arbitrarily illustrated for convenience of explanation, the disclosure is not limited thereto.

The X-axis, the Y-axis, and the Z-axis are not limited to three axes of the rectangular coordinate system and may be interpreted in a broader sense. For example, the X-axis, the Y-axis, and the Z-axis may be perpendicular to one another or may represent different directions that are not perpendicular to one another.

When a certain embodiment is implemented differently, a specific process sequence may be performed differently from a sequence described herein. For example, two consecutively described processes may be performed substantially at the same time or performed in an order opposite to the stated order.

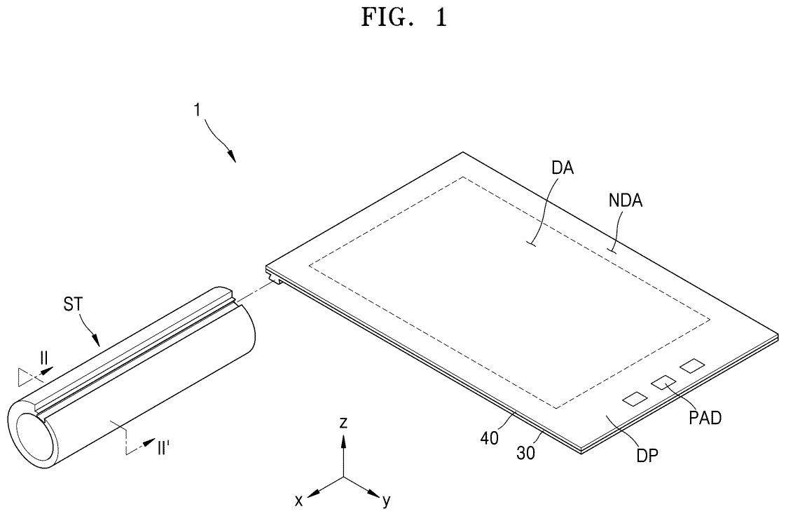

FIG. 1 is a schematic exploded perspective view of a display apparatus 1 according to an embodiment.

Referring to FIG. 1, the display apparatus 1 according to an embodiment may be a rollable display apparatus. Specifically, the display apparatus 1 according to an embodiment may include a shaft ST and a display portion DP which may be wound around the shaft ST in the form of a roll. That is, FIG. 1 illustrates the display apparatus 1 with the display portion DP unfolded (also referred to herein as an unwound state of the display apparatus 1 or the display portion DP).

The shaft ST may be coupled to one end of the display portion DP, and the display portion DP may be wound around the shaft ST. The display portion DP may be flexible. The following description focuses on the display portion DP.

The display apparatus 1 may include a display area DA in which an image is implemented and a non-display area NDA in which an image is not implemented. The display apparatus 1 may provide an image through an array of a plurality of sub-pixels two-dimensionally arranged in the display area DA on an xy plane. The sub-pixels may emit different colors. For example, the sub-pixels may each be one of a red sub-pixel, a green sub-pixel, and a blue sub-pixel.

In an embodiment, the sub-pixels may include a first sub-pixel, a second sub-pixel, and a third sub-pixel. Hereinafter, for convenience of explanation, a case where the first sub-pixel is a red sub-pixel, the second sub-pixel is a green sub-pixel, and the third sub-pixel is a blue sub-pixel is described, and embodiments of the present disclosure are not limited thereto.

The first sub-pixel, the second sub-pixel, and the third sub-pixel are areas in which red light (Lr), green light (Lg), and blue light (Lb) are emitted, and the display apparatus 1 may provide an image by using the emitted light.

The non-display area NDA is an area in which an image is not provided and may surround at least a portion of the display area DA. In an embodiment, the non-display area NDA may completely surround the display area DA. A driver or a main voltage line configured to provide electrical signals or power to pixel circuits may be arranged in the non-display area NDA. A pad PAD, which is an area to which an electronic device or a printed circuit board may be electrically connected, may be arranged in the non-display area NDA.

The display area DA may have a polygonal shape including a rectangular shape, as illustrated in FIG. 1. For example, the display area DA may have a rectangular shape in which a horizontal length is greater than a vertical length, a rectangular shape in which a horizontal length is less than a vertical length, or a square shape. In another embodiment, the display area DA may have a circular shape, an elliptical shape, or a polygonal shape, such as, for example, a triangular shape or a pentagonal shape. In some aspects, the display apparatus 1 of FIG. 1 is illustrated as an example of a rollable display apparatus, but the display apparatus 1 may be implemented in various forms, such as, for example, flexible, foldable, or flat display apparatuses.

In an embodiment, the display apparatus 1 may be an organic light-emitting display apparatus. In another embodiment, the display apparatus 1 may be an inorganic light-emitting display apparatus or a quantum dot light-emitting display apparatus. For example, an emission layer of a display element included in the display apparatus may include an organic material, an inorganic material, or quantum dots, may include an organic material and quantum dots, may include an inorganic material and quantum dots, or may include an organic material, an inorganic material, and quantum dots. Hereinafter, for convenience of explanation, a detailed description is given focusing on a case where the display apparatus 1 is an organic light-emitting display apparatus.

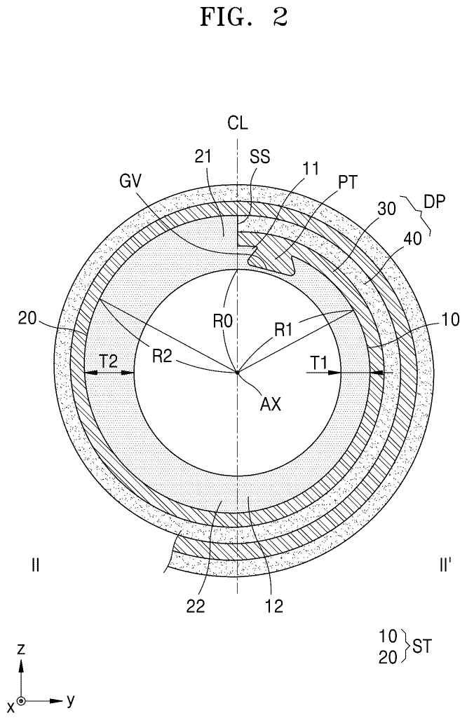

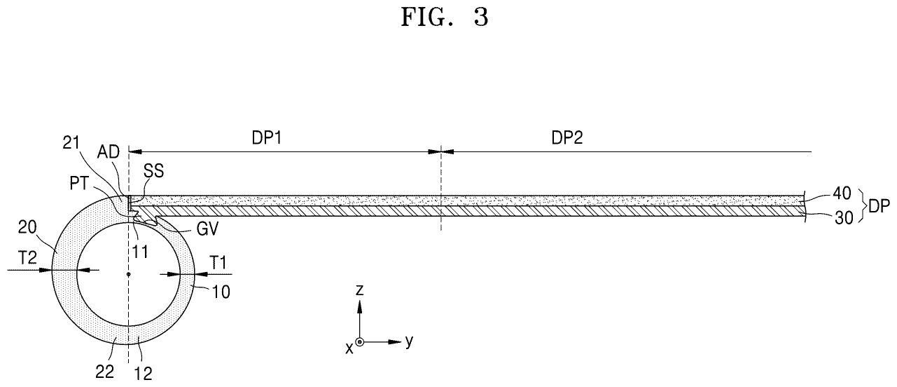

FIG. 2 is a schematic cross-sectional view of the display apparatus of FIG. 1 taken along line II-II′ of FIG. 1, according to an embodiment. In some aspects, FIG. 2 illustrates a state in which the display portion DP is partially wound around the shaft ST (also referred to herein as a partially wound state of the display apparatus 1 or the display portion DP). It is to be understood that descriptions herein of the partially wound state support a fully wound state of the display apparatus 1 or the display portion DP. FIG. 3 is a schematic cross-sectional view of the display apparatus according to an embodiment and may include aspects described with reference to FIG. 2. In some aspects, FIG. 3 illustrates a state in which the display portion DP is not wound around the shaft ST.

Referring to FIG. 2, the shaft ST may have a cylindrical shape with a hollow interior. Specifically, the shaft ST may extend in a first direction (e.g., an x direction of FIG. 2). In some embodiments, the shaft ST has a hollow interior, and accordingly, the shaft ST may have a substantially ring shape in a cross section perpendicular to the first direction. In another embodiment, the shaft ST may have a filled interior instead of a hollow interior. Hereinafter, for convenience of explanation, a description is given focusing on a case where the shaft ST has a hollow interior.

In an embodiment, the shaft ST may include a first half ring portion 10 and a second half ring portion 20. The first half ring portion 10 and the second half ring portion 20 may each have the shape of a half ring to constitute the shaft ST. That is, as illustrated in the cross section of FIG. 2, the first half ring portion 10 may be a half ring on one side of the shaft ST, for example, the right side of the shaft ST (a +y direction side of FIG. 2) with respect to a center line CL passing through a central shaft AX of the shaft ST. In some aspects, as illustrated in the cross section of FIG. 2, the second half ring portion 20 may be a half ring on the other side of the shaft ST, for example, the left side of the shaft ST (a −y direction side of FIG. 2) with respect to the center line CL passing through the central shaft AX of the shaft ST.

The first half ring portion 10 may have a first end portion 11 and a second end portion 12. The first end portion 11 may be one end portion of the half ring, for example, an upper end portion (a +z direction side of FIG. 2). The second end portion 12 may be the other end portion of the half ring facing the first end portion 11, for example, a lower end portion (a −z direction side of FIG. 2). That is, the first end portion 11 and the second end portion 12 may respectively refer to both end portions of the first half ring portion 10. A central angle between the first end portion 11 and the second end portion 12 may be about 180°.

The second half ring portion 20 may have a third end portion 21 and a fourth end portion 22. The third end portion 21 may be one end portion of the half ring, for example, an upper end portion (the +z direction side of FIG. 2). The fourth end portion 22 may be the other end portion of the half ring facing the third end portion 21, for example, a lower end portion (the −z direction side of FIG. 2). That is, the third end portion 21 and the fourth end portion 22 may respectively refer to both end portions of the second half ring portion 20. A central angle between the third end portion 21 and the fourth end portion 22 may be about 180°.

In some embodiments, the first half ring portion 10 and the second half ring portion 20 may be connected to each other. Specifically, the first end portion 11 of the first half ring portion 10 and the third end portion 21 of the second half ring portion 20 may be connected to each other, and the second end portion 12 of the first half ring portion 10 and the fourth end portion 22 of the second half ring portion 20 may be connected to each other. Accordingly, for example, the first half ring portion 10 and the second half ring portion 20 may be connected to each other and have a substantially ring shape. In order to more easily describe the shape and configuration of the shaft ST, the first half ring portion 10 and the second half ring portion 20 are described as separate configurations, but the first half ring portion 10 and the second half ring portion 20 may be formed as one piece.

In a cross-sectional view, the inner surface of the first half ring portion 10 may form the inner hollow of the shaft ST and may have the shape of a semicircle curved to have a constant curvature radius RO. In some aspects, the inner surface of the second half ring portion 20 may form the inner hollow of the shaft ST and may have the shape of a semicircle curved to have a constant curvature radius R0. That is, the inner surface of the first half ring portion 10 and the inner surface of the second half ring portion 20 may be connected to each other and may have the shape of a circle with the same curvature radius R0, such that the inner surfaces for a continuous curved surface.

In some embodiments, in a cross-sectional view, the outer surface of the first half ring portion 10 may form a continuous curved surface. The outer surface of the first half ring portion 10 may be curved such that a curvature radius R1 gradually increases from the first end portion 11 to the second end portion 12 (e.g., in a clockwise direction). In other words, a thickness T1 of the first half ring portion 10 may vary, such that the thickness T1 gradually increases from the first end portion 11 to the second end portion 12 (e.g., a clockwise direction). That is, the thickness T1 of the first half ring portion 10 at the second end portion 12 may be greater than the thickness T1 of the first half ring portion 10 at the first end portion 11.

In some embodiments, in a cross-sectional view, the outer surface of the first half ring portion 10 may form a continuous curved surface. The outer surface of the second half ring portion 20 may be curved such that a curvature radius R2 gradually increases from the fourth end portion 22 to the third end portion 21 (e.g., in a clockwise direction). In other words, a thickness T2 of the second half ring portion 20 may vary, such that the thickness T2 gradually increases from the fourth end portion 22 to the third end portion 21 (e.g., a clockwise direction). That is, the thickness T2 of the second half ring portion 20 at the third end portion 21 may be greater than the thickness T2 of the second half ring portion 20 at the fourth end portion 22.

In some embodiments, the outer surface of the second end portion 12 of the first half ring portion 10 and the outer surface of the fourth end portion 22 of the second half ring portion 20, which are connected to each other, may form a continuous surface. That is, the shaft ST may be formed such that a step is not be formed between the outer surface of the second end portion 12 of the first half ring portion 10 and the outer surface of the fourth end portion 22 of the second half ring portion 20. For example, a portion where the second end portion 12 and the fourth end portion 22 are in contact with each other may have the same curvature radius. Accordingly, for example, the thickness of the shaft ST may continuously vary over the first end portion 11 and the second end portion 12 of the first half ring portion 10, and the thickness of the shaft ST may continuously vary over the fourth end portion 22 and the third end portion 21 of the second half ring portion 20. Accordingly, for example, when viewed in a direction of the central shaft AX, the outer surface of the shaft ST may be spiral shaped and include at least one rotation starting from the first end portion 11 to the stepped surface SS with respect to the central shaft AX.

In some embodiments, the outer surface of the first end portion 11 of the first half ring portion 10 and the outer surface of the third end portion 21 of the second half ring portion 20, which are connected to each other, may form a noncontinuous surface. Specifically, for example, the shaft ST is formed to have a thickness that continuously increases over the first end portion 11 of the first half ring portion 10 to the third end portion 21 of the second half ring portion 20 (in a clockwise direction), in which the thickness T2 of the third end portion 21 may be greater than the thickness T1 of the first end portion 11 at a portion where the first end portion 11 and the third end portion 21 are in contact with each other. Accordingly, the second half ring portion 20 may have a stepped surface SS, and the thickness of the stepped surface SS may be greater than the thickness of the first end portion 11 of the first half ring portion 10 at the third end portion 21. In some embodiments, the stepped surface SS of the second half ring portion 20 may correspond to the difference between the thickness of the third end portion 21 and the thickness of the first end portion 11. As described herein, the display portion DP may be connected to and fixed to the stepped surface SS of the second half ring portion 20.

In an embodiment, the first half ring portion 10 may include a groove GV. The groove GV may be arranged adjacent to the first end portion 11. The groove GV may be concavely formed in the thickness direction of the first half ring portion 10, for example, from the outer surface to the inner surface of the first half ring portion 10, and may extend in the first direction (e.g., the x direction of FIG. 2). A protrusion PT of the display portion DP, which will be described herein, may be fitted into the groove GV.

In an embodiment, the groove GV may become wider in the thickness direction of the first half ring portion 10, for example, from the outer surface to the inner surface of the first half ring portion 10. For example, the groove GV may be trapezoidal shaped, and the width of the groove GV may increase in the thickness direction. However, it will be understood that the disclosure is not limited thereto, and for example, the groove GV may be circular shaped or may be provided in other polygonal shapes. Accordingly, providing the groove GV as a trapezoidal shape, a circular shape, or other polygonal shape and providing the protrusion PT as a shape corresponding to the groove GV as described herein may further increase a fastening force between the groove GV and the protrusion PT coupled to the groove GV.

Referring to FIGS. 2 and 3, the display portion DP may be wound around the shaft ST. FIG. 2 illustrates an example in which the display portion DP is in a wound state (partially or fully wound), and FIG. 3 illustrates an example in which the display portion DP is in an unwound state. The display portion DP may be arranged such that the display portion DP surrounds the first half ring portion 10 and the second half ring portion 20 from the first end portion 11 of the first half ring portion 10, for example, in a clockwise direction. The display portion DP may include a base layer 30 and a display module 40 disposed on the base layer 30.

In some aspects, the display portion DP may include a dummy area DP1 and a support area DP2 connected to the dummy area DP1. One end portion (e.g., the −y direction side of FIG. 3) of the dummy area DP1 may be fixed to the upper portion of the first end portion 11 of the first half ring portion 10. In an embodiment, an end portion of the dummy area DP1 may be fixed to the stepped surface SS of the second half ring portion 20. For example, an adhesive layer AD may be between an end portion of the dummy area DP1 (e.g., at an end portion of the display module 40 and at an end portion of the base layer 30) and the stepped surface SS of the second half ring portion 20. Accordingly, the end portion (one end portion) of the dummy area DP1 may be bonded to the stepped surface SS.

In some embodiments, the thickness of the stepped surface SS of the second half ring portion 20, that is, the difference T2-T1 between the thickness T2 of the third end portion 21 of the second half ring portion 20 and the thickness T1 of the first end portion 11 of the first half ring portion 10 may correspond to the sum of the thickness of the display portion DP, that is, the base layer 30, and the thickness of the display module 40. For example, a difference between the difference T2-T1 between the thickness T2 of the third end portion 21 of the second half ring portion 20 and the thickness T1 of the first end portion 11 of the first half ring portion 10 and the sum of the thickness of the base layer 30 and the thickness of the display module 40 may be 40 μm or less.

In some embodiments, the difference T2-T1 between the thickness T2 of the third end portion 21 of the second half ring portion 20 and the thickness T1 of the first end portion 11 of the first half ring portion 10 may be greater than the sum of the thickness of the base layer 30 and the thickness of the display module 40 by 40 μm or less. Specifically, for example, the difference T2-T1 may be greater than the sum of the thickness of the base layer 30 and the thickness of the display module 40 by 10 μm or less. More specifically, the difference T2-T1 may be equal to the sum of the thickness of the base layer 30 and the thickness of the display module 40. Accordingly, the display portion DP may be smoothly connected at a portion where the display portion DP is connected to and fixed to the stepped surface SS of the second half ring portion 20, without forming a step on the outer surface of the second half ring portion 20.

In some aspects, the protrusion PT may be formed on the lower surface of the display portion DP, that is, the lower surface of the base layer 30 (a −z direction surface of FIG. 3). In some aspects, the lower surface of the base layer 30 may refer to a surface facing the outer surface of the first half ring portion 10.

The protrusion PT may protrude toward the outer surface of the first half ring portion 10, may extend in the first direction (e.g., the x direction of FIG. 3), and may be arranged at a position adjacent to one end portion of the dummy area DP1. In some aspects, the protrusion PT may be formed at a position facing the groove GV of the first half ring portion 10 such that the protrusion PT corresponds to the groove GV of the first half ring portion 10, and the protrusion PT may be fitted into the groove GV of the first half ring portion 10. The protrusion PT may be formed in a shape corresponding to the groove GV. For example, the protrusion PT may be trapezoidal shaped, and the width of the protrusion PT may increase in the protruding direction.

Accordingly, the display portion DP, particularly the base layer 30, may be firmly fixed to the shaft ST without a separate member, such as, for example, an attachment film disposed on the outer surface of the first half ring portion 10. In some aspects, embodiments of the present disclosure may include attaching the display portion DP to the shaft ST, for example, without providing an attachment film between the outer surface of the first half ring portion 10 and the display portion DP, and thus, a step may not occur between the shaft ST and the display portion DP. In a comparative example in which a step is formed between the shaft ST and the display portion DP and the display portion DP is wound around the shaft ST, stress may be applied to a portion where the step is formed, thus causing the display module 40 of the display portion DP to be damaged. As described herein, embodiments of the present disclosure include preventing a step from being formed when the display portion DP is wound around the shaft ST, thereby preventing damage and/or crease of the display portion DP due to the formation of such a step.

Furthermore, in the present embodiments, descriptions have been given focusing on, in addition to the fixing of the display portion DP to the first half ring portion 10 by the protrusion PT, the bonding and fixing of one end portion of the display portion DP to the stepped surface SS of the second half ring portion 20, but the disclosure is not limited thereto. For example, in another embodiment, an end portion of the display portion DP is not bonded to the stepped surface SS of the second half ring portion 20 but may be fixed to the first half ring portion 10 by the protrusion PT (e.g., only by the protrusion PT).

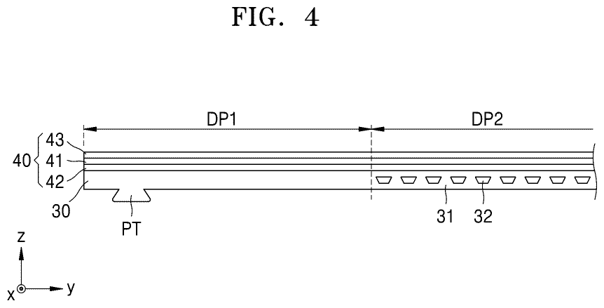

In some embodiments, the dummy area DP1 may be wound around the outer surface of the shaft ST, starting from the first end portion 11 of the first half ring portion 10. In some embodiments, similar to the dummy area DP1, the support area DP2 connected to the dummy area DP1 may also be wound around the outer surface of the shaft ST. In some embodiments, the dummy area DP1 may surround at least a portion of the outer surface of the shaft ST. For example, in the wound state of the display apparatus 1 (e.g., wound state of the display portion DP) the dummy area DP1 may overlap and surround a portion of the outer surface of the shaft ST, for example, half of the outer surface of the shaft ST, and the support area DP2 may overlap and surround another portion of the outer surface of the shaft ST, for example, the remaining half of the outer surface of the shaft ST. In some embodiments, the dummy area DP1 may cover less than half of the outer surface of the shaft ST, and the support area DP2 may overlap and surround the remaining portion of the outer surface of the shaft ST. Alternatively, in another embodiment, the dummy area DP1 may overlap and surround the shaft ST, that is, the first half ring portion 10 and the second half ring portion 20, one or more times, such that the support area DP2 may not be in direct contact with the shaft ST. Accordingly, for example, the dummy area DP1 may surround or wrap around the shaft ST, that is, the first half ring portion 10 and the second half ring portion 20, one or more times. In some aspects, in the wound state of the display apparatus 1 (e.g., wound state of the display portion DP), a quantity of times by which the dummy area DP1 wraps around the shaft ST may be based on the length of the dummy area DP1. As described herein, a support 32 may be arranged in the support area DP2, and the support 32 may not be arranged in the dummy area DP1. For example, in some embodiments, (as illustrated at FIG. 4), the supports 32 may be arranged only in the support area DP2. Accordingly, the adhesion between the shaft ST and the dummy area DP1 that is in direct contact with the shaft ST may be improved.

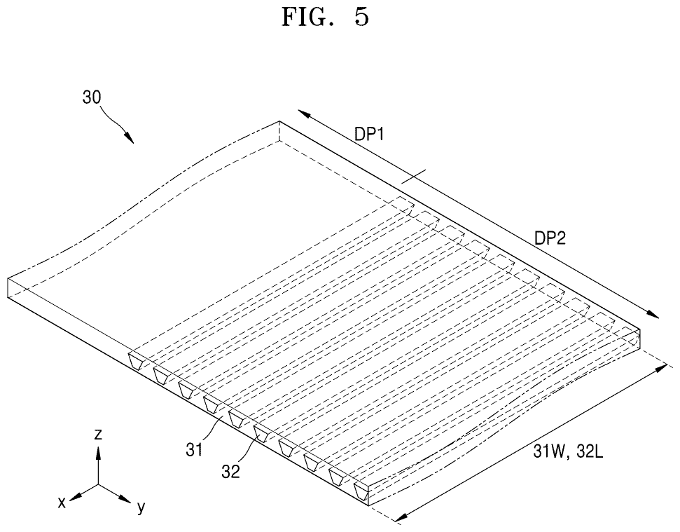

FIG. 4 is a schematic cross-sectional view of the display portion DP according to an embodiment. FIG. 5 is a schematic perspective view of the base layer 30 according to an embodiment.

Referring to FIGS. 4 and 5, the display portion DP may include the base layer 30 and the display module 40 disposed on the base layer 30. In some aspects, the display module 40 may include a display panel 41, a protection film 42, and a cover window 43.

The base layer 30 may support the display module 40 and may include a basic layer 31 and a plurality of supports 32. The supports 32 may be arranged in the basic layer 31 such that the supports 32 are spaced apart from each other and parallel to each other. Each of the supports 32 may extend in the first direction (the x direction of FIG. 4).

As illustrated in FIG. 5, a width 31W of the basic layer 31 in the first direction may be substantially equal to a length 32L of each of the supports 32 in the first direction. Accordingly, both tip surfaces of each of the supports 32 may form a continuous surface with side surfaces of the basic layer 31. Descriptions of both tip surfaces of each of the supports 32 forming a continuous surface with the side surfaces of the basic layer 31 means that both tip surfaces of each of the supports 32 are not located within the basic layer 31 but are exposed to the outside. In another embodiment, both tip surfaces of each of the supports 32 may protrude without forming a continuous surface with the side surfaces of the basic layer 31. That is, the length 32L of each of the supports 32 in the first direction may be greater than the width 31W of the basic layer 31 in the first direction. Accordingly, both end portions of each of the supports 32 may protrude from the side surface of the basic layer 31.

As described herein, in an embodiment, the display portion DP may be implemented without arranging or including the supports 32 in the dummy area DP1. That is, in the dummy area DP1, the base layer 30 may include the basic layer 31 and may be absent the supports 32. For example, in the dummy area DP1, the base layer 30 may include only the basic layer 31. Accordingly, the adhesion between the base layer 30 and the outer surface of the shaft ST may be improved in the dummy area DP1 that is in direct contact with the shaft ST. However, the disclosure is not limited thereto. In another embodiment, the base layer 30 in the dummy area DP1 may include a plurality of supports 32.

In an embodiment, the modulus of the basic layer 31 may be lower than the modulus of each of the supports 32. Accordingly, for example, the basic layer 31 may include silicon or a curable resin such as, for example, polyurethane acrylate, and the supports 32 may each include metal or carbon fiber reinforced plastic (CFRP). The supports 32 may prevent the display portion DP from sagging by supporting the display portion DP in a state in which the display portion DP is unwound. In some aspects, the supports 32 may prevent the display module 40 from being distorted in a process during which the display portion DP is wound around the shaft ST.

The display panel 41 may be disposed on the base layer 30. The display panel 41 may display an image on an upper surface, for example, on the back surface of the surface facing the base layer 30. The display panel 41 may include a display area and a non-display area. A pixel circuit and a display element electrically connected to the pixel circuit may be arranged in the display area, and a scan driving circuit or a driver may be arranged in the non-display area. Like the base layer 30, the display panel 41 may be flexible. The display panel 41 is described in detail below with reference to FIG. 5.

The protection film 42 may be between the display panel 41 and the base layer 30. In particular, the protection film 42 may protect the display panel 41 from impact resistance. In an embodiment, the protection film 42 may include polyethylene terephthalate (PET).

In some aspects, the cover window 43 may be disposed such that the cover window 43 covers the display panel 41 and protects the display panel 41 from external impact. The cover window 43 may be arranged on a side opposite to the protection film 42 with the display panel 41 between the cover window 43 and the protection film 42.

The cover window 43 may be, for example, a flexible window. The cover window 43 may be easily bent according to an external force without causing cracks or the like, thereby protecting the display panel 41. The cover window 43 may include at least one of glass, sapphire, or plastic. The cover window 43 may include, for example, ultra-thin glass or colorless polyimide. In an embodiment, the cover window 43 may have a structure in which a flexible polymer layer is disposed on one side of a glass substrate. In another embodiment, the cover window 43 may include only a polymer layer.

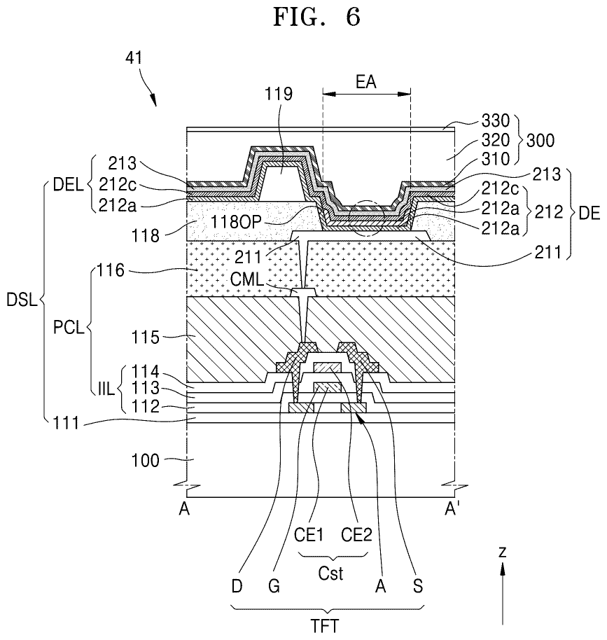

FIG. 6 is a schematic cross-sectional view of a display panel according to an embodiment.

Referring to FIG. 6, the display panel 41 may include a substrate 100, a display layer DSL, and an encapsulation layer 300.

The display layer DSL may be disposed on the substrate 100. The display layer DSL may include a buffer layer 111, a pixel circuit layer PCL, and a display element layer DEL.

The substrate 100 may include glass or polymer resin, such as, for example, polyethersulfone, polyarylate, polyetherimide, polyethylene naphthalate, polyethylene terephthalate, polyphenylene sulfide, polyimide, polycarbonate, cellulose triacetate, or cellulose acetate propionate. The substrate 100 including the polymer resin may be flexible, rollable, or bendable. The substrate 100 may have a multilayer structure that includes a barrier layer (not illustrated) and a base layer including the polymer resin described herein.

The buffer layer 111 may include an inorganic insulating material, such as, for example, silicon nitride, silicon oxynitride, or silicon oxide, and may include a single layer or layers including the inorganic insulating material described herein.

The pixel circuit layer PCL may be disposed on the buffer layer 111. The pixel circuit layer PCL may include a transistor TFT included in a pixel circuit and may include an inorganic insulating layer IIL, a first planarization layer 115, and a second planarization layer 116, which are disposed below and/or above the transistor TFT. The inorganic insulating layer IIL may include a first gate insulating layer 112, a second gate insulating layer 113, and an interlayer insulating layer 114.

The transistor TFT may include a semiconductor layer A, and the semiconductor layer A may include polysilicon. Alternatively, the semiconductor layer A may include amorphous silicon, an oxide semiconductor, or an organic semiconductor. The semiconductor layer A may include a channel region, and a drain region and a source region respectively on both sides of the channel region. A gate electrode G may overlap the channel region.

The gate electrode G may include a low-resistance metal material. The gate electrode G may include a conductive material including molybdenum (Mo), aluminum (Al), copper (Cu), titanium (Ti), and the like, and may include a single layer or layers including the conductive material described herein.

The first gate insulating layer 112 between the semiconductor layer A and the gate electrode G may include an inorganic insulating material, such as, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be ZnO and/or ZnO₂.

The second gate insulating layer 113 may cover the gate electrode G. Similar to the first gate insulating layer 112, the second gate insulating layer 113 may include an inorganic insulating material, such as, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be ZnO and/or ZnO₂.

An upper electrode CE2 of a storage capacitor Cst may be disposed on the second gate insulating layer 113. The upper electrode CE2 may overlap the gate electrode G, below the gate electrode G. In this case, the gate electrode G and the upper electrode CE2, which overlap each other with the second gate insulating layer 113 between the gate electrode G and the upper electrode CE2, may constitute the storage capacitor Cst. That is, the gate electrode G may function as a lower electrode CE1 of the storage capacitor Cst. As described herein, the storage capacitor Cst and the transistor TFT may overlap each other. In some embodiments, the storage capacitor Cst may not overlap the transistor TFT.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may include a single layer or layers including the material described herein.

The interlayer insulating layer 114 may cover the upper electrode CE2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be ZnO and/or ZnO₂. The interlayer insulating layer 114 may include a single layer or layers including the inorganic insulating material described herein.

A drain electrode D and a source electrode S may be disposed on the interlayer insulating layer 114. The drain electrode D and the source electrode S may each include a material having good conductivity. The drain electrode D and the source electrode S may each include a conductive material including molybdenum (Mo), aluminum (Al), copper (Cu), titanium (Ti), and the like, and may each include a single layer or layers including the conductive material described herein. In an embodiment, the drain electrode D and the source electrode S may each have a multilayer structure of Ti/Al/Ti.

The first planarization layer 115 may be disposed such that the first planarization layer 115 covers the drain electrode D and the source electrode S. The first planarization layer 115 may include an organic insulating material. The first planarization layer 115 may include an organic insulating material selected from general-purpose polymer, such as, for example, polymethylmethacrylate (PMMA) or polystyrene (PS), polymer derivatives having a phenolic group, acrylic polymer, imide-based polymer, aryl ether-based polymer, amide-based polymer, fluorine-based polymer, p-xylene-based polymer, vinyl alcohol-based polymer, and any blend thereof.

A connection electrode CML may be disposed on the first planarization layer 115. In some embodiments, the connection electrode CML may be connected to the drain electrode D or the source electrode S through a contact hole of the first planarization layer 115. The connection electrode CML may include a material having good conductivity. The connection electrode CML may include a conductive material including molybdenum (Mo), aluminum (Al), copper (Cu), titanium (Ti), and the like, and may include a single layer or layers including the conductive material described herein. In an embodiment, the connection electrode CML may have a multilayer structure of Ti/Al/Ti.

The second planarization layer 116 may be disposed such that the second planarization layer 116 covers the connection electrode CML. The second planarization layer 116 may include an organic insulating layer. The second planarization layer 116 may include an organic insulating material selected from general-purpose polymer, such as, for example, PMMA or PS, polymer derivatives having a phenolic group, acrylic polymer, imide-based polymer, aryl ether-based polymer, amide-based polymer, fluorine-based polymer, p-xylene-based polymer, vinyl alcohol-based polymer, and any blend thereof.

The display element layer DEL may be disposed on the pixel circuit layer PCL. The display element layer DEL may include a display element DE. The display element DE may be an organic light-emitting diode (OLED). A pixel electrode 211 of the display element DE may be electrically connected to the connection electrode CML through a contact hole of the second planarization layer 116.

The pixel electrode 211 may include a conductive oxide, such as, for example, indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 211 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. In another embodiment, the pixel electrode 211 may further include a layer including ITO, IZO, ZnO, or In₂O₃ above and/or below the reflective layer.

A pixel defining layer 118 having an opening 118OP exposing the central portion of the pixel electrode 211 may be disposed on the pixel electrode 211. The pixel defining layer 118 may include an organic insulating material and/or an inorganic insulating material. The opening 118OP may define an emission area for light emitted from the display element DE (hereinafter referred to as an emission area EA). For example, the width of the opening 118OP may correspond to the width of the emission area EA of the display element DE.

A spacer 119 may be disposed on the pixel defining layer 118. In a method of manufacturing a display apparatus, the spacer 119 may prevent damage to the substrate 100. A mask sheet may be used when manufacturing the display panel. In some embodiments, when the mask sheet is inserted into the opening 118OP of the pixel defining layer 118 or when the mask sheet is in close contact with the pixel defining layer 118 and a deposition material is deposited on the substrate 100, the spacer 119 may prevent defects in which a portion of the substrate 100 is damaged or broken by the mask sheet.

The spacer 119 may include an organic insulating material such as, for example, polyimide. Alternatively, the spacer 119 may include an inorganic insulating material, such as, for example, silicon nitride or silicon oxide, or may include an organic insulating material and an inorganic insulating material.

In an embodiment, the spacer 119 may include a material that is different from a material of the pixel defining layer 118. Alternatively, in another embodiment, the spacer 119 may include the same material as the material of the pixel defining layer 118. In this case, the pixel defining layer 118 and the spacer 119 may be formed together in a mask process using a half-tone mask or the like.

An intermediate layer 212 may be disposed on the pixel defining layer 118. The intermediate layer 212 may include an emission layer 212b arranged in the opening 118OP of the pixel defining layer 118. The emission layer 212b may include a high molecular weight organic material or a low molecular weight organic material that emits light of a certain color. It is to be understood that relative terms such as, for example, “high,” “low,” and the like may refer to the characteristics satisfying (e.g., being greater than, less than, or the like) a threshold associated with the characteristics.

A first functional layer 212a and a second functional layer 212c may be respectively disposed below and above the emission layer 212b. For example, the first functional layer 212a may include a hole transport layer (HTL), or may include an HTL and a hole injection layer (HIL). The second functional layer 212c may be optionally disposed on the emission layer 212b. The second functional layer 212c may include an electron transport layer (ETL) and/or an electron injection layer (EIL). The first functional layer 212a and/or the second functional layer 212c may be a common layer completely covering the substrate 100, like an opposite electrode 213 to be described herein.

The opposite electrode 213 may include a conductive material having a low work function. For example, the opposite electrode 213 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the opposite electrode 213 may further include a layer including ITO, IZO, ZnO, or In₂O₃ on the (semi) transparent layer including the material described herein.

In some embodiments, a capping layer (not illustrated) may be further disposed on the opposite electrode 213. The capping layer may include LiF, an inorganic material, or/and an organic material.

An encapsulation layer 300 may be disposed on the opposite electrode 213. The encapsulation layer 300 may be disposed on the display element layer DEL and may cover the display element layer DEL. The encapsulation layer 300 may include at least one inorganic encapsulation layer and at least one organic encapsulation layer. In an embodiment, FIG. 6 illustrates that the encapsulation layer 300 includes a first inorganic encapsulation layer 310, an organic encapsulation layer 320, and a second inorganic encapsulation layer 330, which are sequentially stacked in this stated order.

The first inorganic encapsulation layer 310 and the second inorganic encapsulation layer 330 may each include at least one inorganic material selected from aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include acrylic resin, epoxy-based resin, polyimide, polyethylene, and the like. In an embodiment, the organic encapsulation layer 320 may include acrylate. The organic encapsulation layer 320 may be formed by curing a monomer or applying a polymer. The organic encapsulation layer 320 may be transparent.

Although not illustrated, a touch sensor layer may be disposed on the encapsulation layer 300, and an optical functional layer may be disposed on the touch sensor layer.

According to one or more embodiments, a rollable display apparatus in which a defect occurrence rate is reduced may be implemented.

The effects of the disclosure are not limited to those described herein, and other effects that are not mentioned herein will be clearly understood from the description of the claims by those of ordinary skill in the art.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a shaft extending in a first direction and comprising:
a first half ring portion having a curvature from a first end portion to a second end portion opposite to the first end portion on a plane perpendicular to the first direction, and
a second half ring portion having a curvature from a third end portion to a fourth end portion opposite to the third end portion on the plane,
wherein the third end portion and the fourth end portion of the second half ring portion are respectively connected to the first end portion and the second end portion of the first half ring portion;
a groove arranged adjacent to the first end portion of the first half ring portion and concavely formed from an outer surface of the first half ring portion in a thickness direction of the first half ring portion;
a base layer configured to overlap the first half ring portion and the second half ring portion from the first end portion in a wound state of the display apparatus, the base layer comprising a protrusion fitted into the groove; and
a display module disposed on the base layer.

2. The display apparatus of claim 1, wherein a width of the groove increases from the outer surface to an inner surface of the first half ring portion.

3. The display apparatus of claim 2, wherein:
the groove is trapezoidal shaped, and
the protrusion is trapezoidal shaped corresponding to a shape of the groove.

4. The display apparatus of claim 1, wherein:
a thickness of the third end portion of the second half ring portion is greater than a thickness of the first end portion of the first half ring portion, and
the second half ring portion comprises a stepped surface, wherein a thickness of the stepped surface is greater than a thickness of the first end portion at the third end portion.

5. The display apparatus of claim 4, wherein the base layer is fixed to the second half ring portion by an adhesive layer between the base layer and the stepped surface of the second half ring portion.

6. The display apparatus of claim 1, wherein a difference between a difference between a thickness of the third end portion of the second half ring portion and a thickness of the first end portion of the first half ring portion and a sum of a thickness of the base layer and a thickness of the display module is 40 μm or less.

7. The display apparatus of claim 1, wherein the display module comprises:
a display panel configured to display an image; and
a cover window disposed such that the cover window covers the display panel.

8. The display apparatus of claim 7, wherein the display module further comprises a protection film between the display panel and the base layer.

9. The display apparatus of claim 1, wherein an outer surface of the second end portion of the first half ring portion and an outer surface of the fourth end portion of the second half ring portion, which are connected to each other, form a continuous surface.

10. The display apparatus of claim 9, wherein:
a thickness of the shaft continuously varies over the first end portion of the first half ring portion to the second end portion of the first half ring portion; and
the thickness of the shaft continuously varies over the fourth end portion of the second half ring portion to the third end portion of the second half ring portion.

11. The display apparatus of claim 9, wherein a thickness of the first end portion of the first half ring portion is less than a thickness of the second end portion of the first half ring portion.

12. The display apparatus of claim 9, wherein a thickness of the fourth end portion of the second half ring portion is less than a thickness of the third end portion of the second half ring portion.

13. The display apparatus of claim 1, wherein a curvature radius associated with an outer surface of the first half ring portion and a curvature radius associated with an outer surface of the second half ring portion each continuously vary.

14. The display apparatus of claim 13, wherein the curvature radius associated with the outer surface of the first half ring portion and the first end portion is less than the curvature radius associated with the outer surface of the first half ring portion and the second end portion.

15. The display apparatus of claim 13, wherein the curvature radius associated with the outer surface of the second half ring portion and the fourth end portion is less than the curvature radius associated with the outer surface of the second half ring portion and the third end portion.

16. The display apparatus of claim 1, wherein the base layer comprises:
a basic layer; and
a plurality of supports arranged in parallel with each other within the basic layer and each extending in the first direction.

17. The display apparatus of claim 16, wherein the basic layer comprises silicon or polyurethane acrylate.

18. The display apparatus of claim 16, wherein:
the base layer comprises a dummy area in which the protrusion is arranged and a support area connected to the dummy area; and
the dummy area wraps around the shaft one or more times in the wound state of the display apparatus, wherein a quantity of times by which the dummy area wraps around the shaft is based on a length of the dummy area.

19. The display apparatus of claim 18, wherein the plurality of supports are not arranged in the dummy area and are arranged in the support area.

20. A display apparatus comprising:
a shaft comprising a central shaft, a first end portion, a stepped surface, and an outer surface, wherein, when viewed in a direction of the central shaft, the outer surface is spiral shaped and comprises one rotation starting from the first end portion to the stepped surface with respect to the central shaft;
a groove concavely formed from the outer surface of the shaft at the first end portion in a thickness direction;
a base layer fitted into the groove and configured to overlap the outer surface of the shaft in a wound state of the display apparatus; and
a display module disposed on the base layer.
